(19) United States
(12) Patent Application Publication
(10) Pub. No.: US 2023/0101417 A1
(43) Pub. Date: Mar. 30, 2023

(54) CAPACITOR STRUCTURE TO SUPPORT VARIABLE SIGNAL AMPLITUDES IN AN ISOLATOR PRODUCT

(71) Applicant: Skyworks Solutions, Inc., Irvine, CA (US)

(72) Inventors: Michael Robert May, Austin, TX (US); Fernando Naim Lavalle Aviles, Austin, TX (US)

(21) Appl. No.: 17/956,024

(22) Filed: Sep. 29, 2022

Related U.S. Application Data
(60) Provisional application No. 63/250,534, filed on Sep. 30, 2021.

(51) Int. Cl. H01L 23/522; H01L 23/64; H01L 23/50; H04B 1/04

(52) U.S. Cl. CPC H01L 23/5223; H01L 23/642; H01L 23/50; H04B 1/04

(57) ABSTRACT

An isolator product includes a capacitor having a first plate formed in a first conductive integrated circuit layer and multiple second plates formed in a second conductive integrated circuit layer. Each second plate of the multiple second plates is separated from a next adjacent second plate by a gap in the second conductive integrated circuit layer. The multiple second plates are concentric.

### CROSS-REFERENCE TO RELATED APPLICATION(S)

This application claims the benefit of U.S. Provisional Application No. 63/250,534, entitled “CAPACITOR STRUCTURE TO SUPPORT VARIABLE SIGNAL AMPLITUDES IN AN ISOLATOR PRODUCT,” naming Michael Robert May and Fernando Naim Lavalle Aviles as inventors, filed on Sep. 30, 2021, which application is incorporated herein by reference.

### BACKGROUND

### Field of the Invention

The invention relates to isolation technology and more particularly to communication across an isolation barrier.

### Description of the Related Art

In a typical control application, a processor system provides one or more control signals for controlling a load system. During normal operation, a large DC or transient voltage difference may exist between the domain of the processor system and the domain of the load system, thus requiring an isolation barrier between the processor system and the load system. For example, one domain may be grounded at a voltage that is switching with respect to earth ground by hundreds or thousands of Volts. Accordingly, an intermediate system includes isolation that prevents damaging currents from flowing between the processor system and the load system. Although the isolation prevents the processor system from being coupled to the load by a direct conduction path, an isolation channel allows communication between the two systems using optical (opto-isolators), capacitive, inductive (transformers), or electromagnetic techniques.

Referring to FIGS. 1 and 2, in an exemplary control application, controller 102, which may be a microprocessor, microcontroller, or other suitable processing device, operates in a first domain (i.e., a voltage domain including V_{DD1}, e.g., 5 Volts (V)) and communicates with load system 110 operating in a second domain (i.e., a voltage domain including V_{DD4}, e.g., 150 V) using isolator 104. Isolator 104 preserves isolation between the domains on a first side of system 100, e.g., the first domain including V_{DD1} (e.g., less than ten volts) and V_{DD2} (e.g., less than ten volts) and devices coupled thereto, and a second side of system 100, e.g., the second domain including V_{DD3} (e.g., tens of Volts) and V_{DD4} (e.g., hundreds of Volts) and devices coupled thereto. For example, the first and second domains of isolator 104 are physically separate while isolator 104 provides a reliable communications channel between the first and second domains.

Isolation communication channel 120 facilitates safe communication of a signal received from controller 102 in the first domain across an isolation barrier to load 110 of the second domain via integrated circuit die 106 and integrated circuit die 108. Similarly, isolator 104 may safely provide at least one feedback signal from load 110 to controller 102 via isolation communication channel 120. The second domain includes driver circuitry (e.g., included in integrated circuit die 108) that generates an output control signal based on the signal received from the first domain and provides a suitable drive signal to load 110. In an exemplary embodiment of isolator 104, integrated circuit die 106 is attached to lead frame 107 and integrated circuit die 108 is attached to lead frame 109. Each integrated circuit die includes integrated circuit terminals coupled to isolation communication channel 120. Integrated circuit die 106, integrated circuit die 108, and isolation communication channel 120 are packaged as a single device.

In an exemplary embodiment, isolated gate driver 104 includes a transmitter in integrated circuit die 106 and a receiver circuit in integrated circuit die 108, which communicate over an isolation communication channel 120. Controller 102 supplies gate information (GATE) to the transmitter circuit in the first voltage domain. The transmitter circuit transmits the gate information to the receiver circuit in the second voltage domain. The receiver circuit uses the gate information to generate a gate drive signal to drive a high-power transistor in load 110 that is used to control the load.

In at least one embodiment of system 100, isolation communication channel 120 blocks DC signals and only passes AC signals. Isolation communication channel 120 is described as including capacitive isolation. Capacitor 113 and capacitor 115 may be integrated with integrated circuit die 106 and integrated circuit die 108, respectively, and coupled to each other via bondwire 114. Capacitor 113 and capacitor 115 may each include a bottom plate formed in a first conductive semiconductor layer (e.g., metal-1), a top plate formed in a second conductive semiconductor layer (e.g., metal-7) above the first conductive semiconductor layer, and a dielectric material (e.g., silicon dioxide) formed between the top and bottom plates.

An exemplary isolation communication channel 120 uses digital modulation, e.g., on-off keying (OOK) modulation, to communicate one or more digital signals between integrated circuit die 106 and integrated circuit die 108, although other communication protocols may be used. In general, on-off keying modulation is a form of amplitude-shift keying modulation that represents digital data as the presence or absence of a carrier wave or oscillating signal having carrier frequency f_{c} (e.g., 300 MHz≤f_{c}≤1 GHz). The presence of the carrier for a specified duration represents a binary one, while its absence for the same duration represents a binary zero. This type of signaling is robust for isolation applications because a logic ‘0’ state sends the same signal (e.g., nothing) as when the first domain loses power and the device gracefully assumes its default state. That behavior is advantageous in driver applications because it will not accidentally turn on the load device, even when the first domain loses power. However, isolator 104 may communicate other types of signals (e.g., pulse width modulated signals or other types of amplitude shift keying modulated signals) across isolation communication channel 120. The digital modulation scheme used may be determined according to performance specifications (e.g., signal resolution) and environment (e.g., probability of transient events) of the target application.

FIG. 3 illustrates conventional OOK modulation. When the GATE signal (e.g., the signal used to drive the gate of a transistor in load 110 of FIG. 1) is a logic ‘0’, the transmitter transmits a steady state signal (e.g., TXP−TXN=0V at 301) on the differential isolation channel, where TXP is the positive transmitted signal and TXN is the negative transmitted signal for a differential pair of signals. When the GATE signal is a logic ‘1’ at 305, the transmitter transmits a high frequency signal over the isolation communication channel, e.g., the signal at 303 with an amplitude of V_{OUT} and with a frequency of 500 MHz. Thus, the presence of the high frequency signal represents a binary one, while its absence represents a binary zero. However, traditional OOK can only send one piece of data at a time.

While the isolated gate driver allows communication of control information across the isolation barrier, improvements in such communication is desirable to provide additional information (e.g., configuration information for more precise control over the system load).

### SUMMARY OF EMBODIMENTS OF THE INVENTION

In at least one embodiment, a capacitor includes a first plate formed in a first conductive integrated circuit layer and multiple second plates formed in a second conductive integrated circuit layer. Each second plate of the multiple second plates is separated from a next adjacent second plate by a gap in the second conductive integrated circuit layer. The multiple second plates are concentric. The multiple second plates may be radially symmetrical.

In at least one embodiment, a method for communicating information across an isolation barrier includes selectively driving each plate of multiple first plates of a capacitor using a full-scale signal according to a first control signal, the capacitor having the multiple first plates and a second plate. The selectively driving may adjust an amplitude of a signal communicated across the isolation barrier using the capacitor. The multiple first plates may be concentric. The multiple first plates may be radially symmetrical.

In at least one embodiment, a method for manufacturing an isolation communication channel includes forming a conductive layer using a substrate and patterning the conductive layer to form multiple plates of a capacitor, each plate of the multiple plates being separated from a next adjacent plate by a gap in the conductive integrated circuit layer. The multiple plates are concentric. The multiple second plates may be radially symmetrical.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a functional block diagram of an exemplary control system including an isolator product.

FIG. 2 illustrates a cross-sectional view of an exemplary packaged isolator product including a capacitive isolation barrier.

FIG. 3 illustrates conventional on-off keying (OOK) signal modulation of the control system of FIG. 1.

FIG. 4 illustrates a system with an isolated gate driver having two isolation communication channels to transmit gate and configuration information.

FIG. 5 illustrates an embodiment of an isolated gate driver that transmits two types of information across a single isolation communication channel.

FIG. 6 illustrates a functional block diagram of an embodiment of an exemplary transmitter circuit.

FIG. 7 illustrates an embodiment of a modulation scheme that allows transmission of configuration information and gate information simultaneously.

FIG. 8 illustrates an embodiment of another modulation scheme that allows transmission of configuration information and gate information simultaneously.

FIG. 9 illustrates a circuit diagram of an exemplary capacitor for use in an isolation communication channel.

FIG. 10 illustrates a circuit diagram of an exemplary capacitor for supporting variable signal amplitudes for communication across an isolation barrier consistent with at least one embodiment of the invention.

FIGS. 11A, 11B, and 11C illustrate exemplary physical designs of capacitor plates having an oval shape consistent with at least one embodiment of the invention.

FIGS. 12A and 12B illustrate exemplary physical designs of capacitor plates having a rounded shape consistent with at least one embodiment of the invention.

FIG. 13 illustrates an exemplary physical design of bottom plates having an octagonal shape consistent with at least one embodiment of the invention.

FIG. 14 illustrates an exemplary physical design of more than two concentric, radially symmetrical bottom plates consistent with at least one embodiment of the invention.

FIG. 15 illustrates a method for manufacturing an isolation communication channel including a capacitor having multiple concentric, radially symmetrical capacitor plates consistent with at least one embodiment of the invention.

FIG. 16 illustrates a functional block diagram of an embodiment of a transmitter circuit of an isolation communication channel consistent with at least one embodiment of the invention.

FIG. 17 illustrates a functional block diagram of an embodiment of a receiver circuit of an isolation communication channel.

FIG. 18 illustrates a functional block diagram of a motor control system including an isolation communication channel consistent with at least one embodiment of the invention.

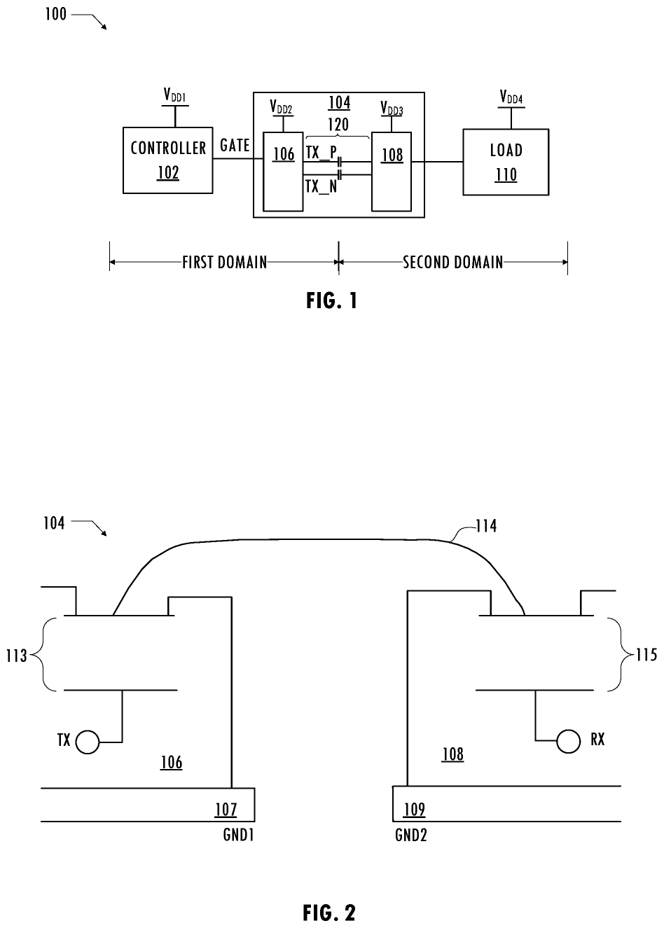

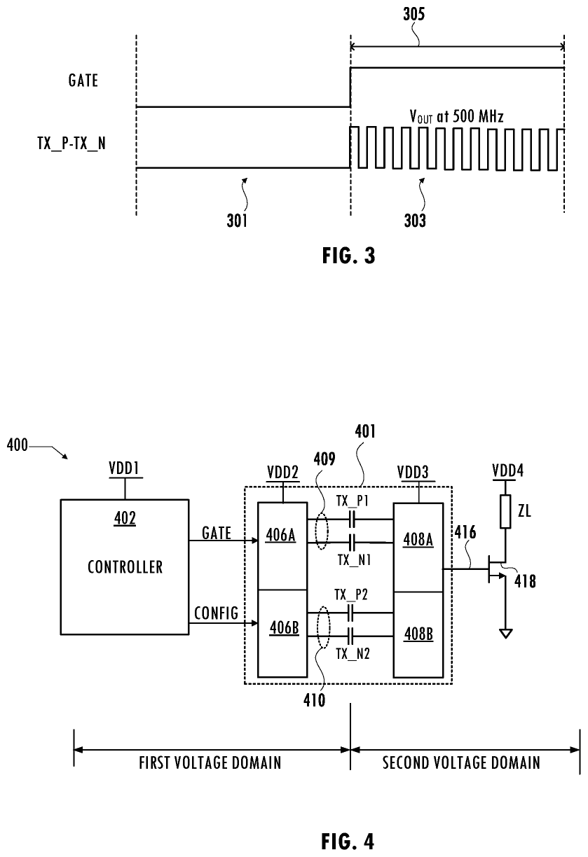

The use of the same reference symbols in different drawings indicates similar or identical items.

### DETAILED DESCRIPTION

A typical CMOS digital isolation solution has a single communication channel. A second isolation communication channel would normally be required to dynamically transmit more than one piece of data (e.g., gate information plus information other than gate information, such as status bits, configuration bits, etc.) across the isolation barrier. In an exemplary application, the gate signal is a critical control function that cannot be delayed while configuration information is being sent. Referring to FIG. 4, in an exemplary application, to provide configuration information (e.g., dynamic drive strength information), in addition to the gate information, system 400 utilizes isolated gate driver 401 with a separate isolation communication channel 410 to send the configuration information. Separate transmitter circuits 406A and 406B transmit the gate and configuration information, respectively, received from controller 402 to receiver circuits 408A and 408B, respectively, on the secondary side utilizing isolation communication channels 409 and 410, respectively. Transmitter circuit 406A transmits the gate information using isolation communication channel 409. Transmitter circuit 406B transmits the configuration information (i.e., information other than gate information) using the isolation communication channel 410. The illustrated isolation communication channels 409 and 410 are differential channels and each transmit a positive signal (TX_P) and a negative signal (TX_N). The illustrated isolation communication channels 409 and 410 utilize capacitive isolation to communicatively couple transmitter circuits 406A and 406B and receive circuits 408A and 408B.

The secondary side includes driver circuitry (e.g., included in receiver circuit 408A), that generates gate signal 416 based on a GATE signal received from the primary side and provides gate signal 416 to the gate of high-power device 418. In at least one embodiment, the high-power device 418 controls power delivered to a load. Exemplary high-power devices include power metal-oxide-semiconductor field-effect transistors (MOSFETs), insulated-gate bipolar transistors (IGBTs), Gallium-Nitride (GaN) MOSFETs, Silicon-Carbide (SiC) power MOSFETs, and other suitable devices able to deliver high power signals.

In at least one embodiment, two aspects of the gate signal 416 are controlled. Receiver circuit 408A controls whether the gate signal is on or off and controls a drive strength of gate signal 416 based on configuration information received from receiver circuit 408B. While providing a communication path for configuration information is beneficial, the second isolation communication channel consumes additional power and requires additional silicon area. In addition, package limitations can often prevent the inclusion of a second isolation communication channel. To overcome package limitations and the disadvantages due to additional power and area of a second isolation communication channel while still providing dynamic configuration information, embodiments described herein send configuration information simultaneously with the main digital gate signal over a single isolation communication channel without affecting the main performance requirements of the main digital signal.

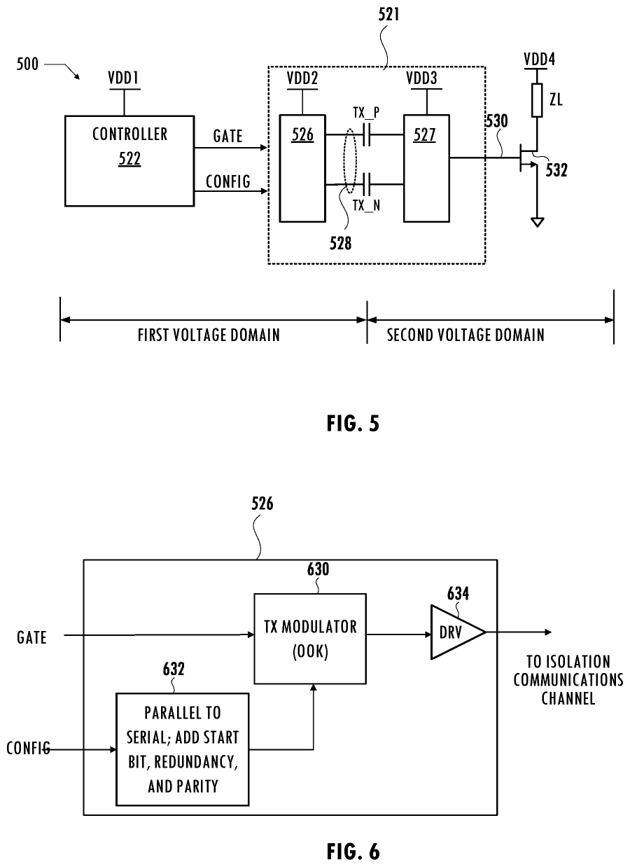

Referring to FIG. 5, in an exemplary embodiment, system 500 includes an isolated gate driver 521 that includes transmitter circuit 526 and receiver circuit 527 communicatively coupled across an isolation barrier via isolation communication channel 528. System 500 includes a primary side integrated circuit (containing transmitter 526) and a secondary side integrated circuit (containing receiver 527) respectively disposed in first and second voltage domains. In embodiments, transmitter circuit 526 is formed on a first integrated circuit die and receiver circuit 527 is formed on a second integrated circuit die, both of which are attached to a lead frame and include terminals coupled to isolation channel 528 formed on the lead frame and packaged as a single device. In still other embodiments, transmitter circuit 526 and receiver circuit 527 include terminals coupled to the isolation communication channel 528, all of which are formed on an integrated circuit die. In still other embodiments transmitter circuit 526 and receiver circuit 527 are integrated circuits included in a multi-chip module. In embodiments, terminals of the transmitter circuit and receiver circuit are coupled to external elements, e.g., transformers, discrete resistors, and discrete capacitors within the multi-chip module, or to terminals of the package of the multi-chip module, and to a package of controller 522.

In at least one embodiment, transmitter circuit 526 and receiver circuit 527 utilize modified on-off keying (OOK) to allow the main digital signal to be sent simultaneously with configuration information over the single isolation communication channel 528. Compared with a two channel implementation shown in FIG. 4 in which one channel is used for the main digital signal and the other channel is used for configuration information, embodiments described herein use a single isolation communication channel thereby consuming less power and utilizing less silicon die area. For example, isolation communication channel 528 carries both gate information for gate signal 530 to drive transistor 532 and drive strength information for the gate signal 530.

FIGS. 5 and 6 illustrate a high level block diagram of an embodiment of transmitter circuit 526 of an isolated gate driver. In the illustrated embodiment, gate information from controller 522 provides the information used for the GATE signal, which is the main digital signal. In addition, transmitter circuit 526 receives configuration information CONFIG. The configuration information may be provided in various forms, such as an analog voltage, a current, a digital voltage, or through resistance values of resistors coupled to input terminals of transmitter circuit 526. The transmitter circuit communicates the configuration information simultaneously with the gate information using isolation communication channel 528. In an embodiment, logic circuit 632 also adds a start bit, parity, and redundancy to the serial word for transmission across the isolation communication channel. Each serial bit is transmitted using the isolation communication channel along with a value of the GATE signal. A typical serial bit time is 1 or 2 μs but other embodiments use a bit time of a different length. Logic circuit 632 supplies the serial word to the transmitter modulator 630, which is described further herein. Transmitter modulator 630 also receives the GATE signal and provides a modified OOK modulated signal to driver 634.

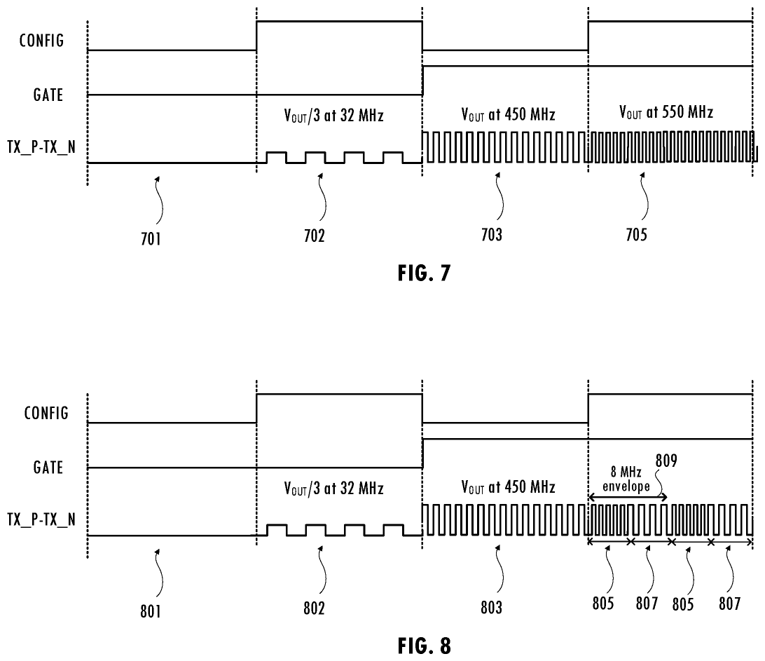

FIG. 7 illustrates an embodiment of a modified OOK modulation scheme that allows sending both configuration information and gate information simultaneously. In contrast with conventional OOK communication, embodiments described herein transmit the main digital signal (e.g., the gate signal) along with configuration (or other) information over the single isolation communication channel. The main digital signal can be a logical one or a zero and at the same time the configuration information can also be a logical one or zero regardless of the logical value of the main digital signal.

To transmit configuration information having a value of CONFIG=0, with GATE=0, a constant voltage is sent as shown at 701. For CONFIG=1 and GATE=0 the signal is modulated at a frequency of 32 MHz and at an amplitude of V_{OUT}/3 as shown at 702. For CONFIG=0 and GATE=1, as shown at 703, the signal is frequency modulated at the OOK frequency and has a second amplitude of V_{OUT}. The second amplitude should be high enough to readily distinguish from the lower amplitude signal when CONFIG=1 and GATE=0. In an embodiment the OOK frequency is 450 MHz. The OOK frequency should be high enough to readily distinguish from the lower frequency signal corresponding to CONFIG=1 and GATE=0. Finally, for GATE=1 and CONFIG=1, the signal is frequency modulated at another frequency, shown at 705. In an embodiment, the frequency shown at 705 is 550 MHz and the frequency shown in 703 is 450 MHz.

FIG. 8 illustrates another embodiment of the modulation scheme that allows sending both configuration information and gate information simultaneously. To transmit configuration information having a value of CONFIG=0, with GATE=0, a constant voltage is sent as shown at 801. For CONFIG=1 and GATE=0 the signal is modulated at a frequency of 32 MHz and at an amplitude of V_{OUT}/3 as shown at 802. For CONFIG=0 and GATE=1, as shown at 803, the signal is frequency modulated at the OOK frequency. In an embodiment, the OOK frequency is 450 MHz. The OOK frequency should be high enough to readily distinguish from the lower frequency signal when CONFIG=1 and GATE=0. Finally, for GATE=1 and CONFIG=1, the signal is frequency modulated at two frequencies during the bit time with a first frequency shown at 805 and a second frequency shown at 807. The frequencies are contained in envelope 809. In an embodiment, the frequency shown at 807 is 450 MHz and the frequency shown in 805 is 550 MHz and the envelope 809 is an 8 MHz envelope.

The modulation schemes of FIGS. 7 and 8 are illustrative only and various other modulation schemes including different frequencies and different fractional-scale amplitudes can be implemented that combine OOK and amplitude modulation of a signal. A conventional approach to amplitude modulating a signal driving the capacitor uses amplitude adjustment at the transmitter side, which requires quickly switching a voltage regulator between two different output voltages. In practice, the voltage switching slows down the transition between full-scale signals and fractional-scale signals. Use of distinct voltage regulator levels could achieve the same goal, but requires that the voltage regulators respond quickly. Use of a completely separate isolation communication channel substantially increases the integrated circuit area. Transmitting the second signal at the same amplitude degrades demodulation of the main, full-scale, high speed channel.

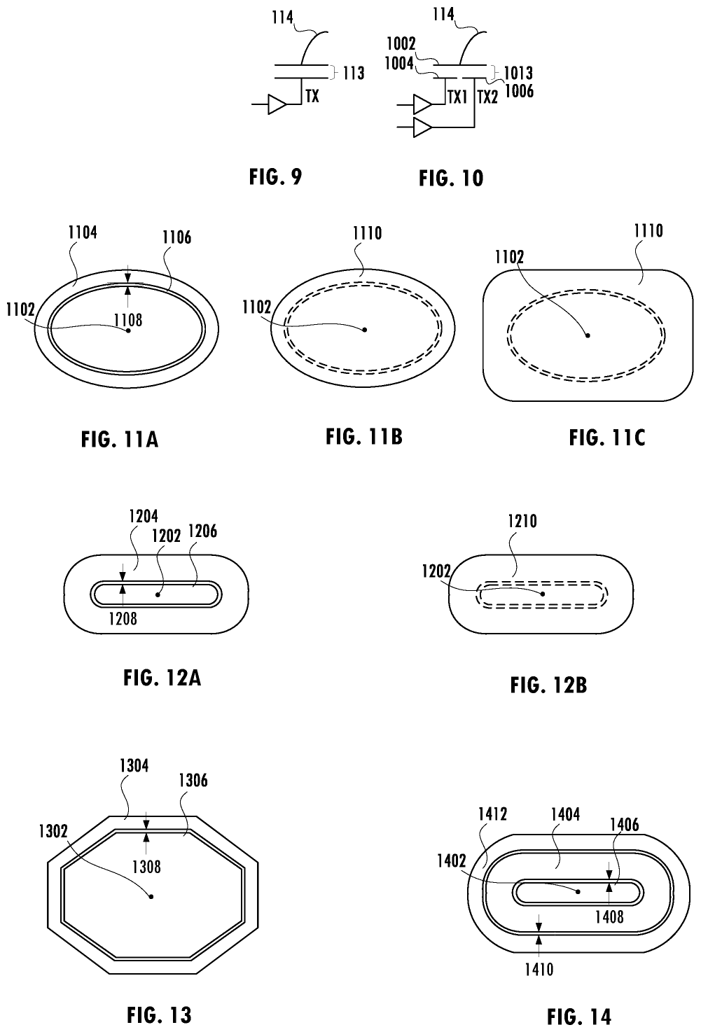

Referring to FIG. 9, an isolation communication channel includes conventional capacitor 113, which includes a top plate (i.e., an upper electrode or positively-charged plate) coupled to bond wire 114 and a bottom plate (i.e., a lower electrode or negatively-charged plate) coupled to a driver of the transmitter. The top plate and the bottom plate are separated by a gap filled with a dielectric material. Rather than driving the bottom plate of capacitor 113 using a voltage regulator that switches between voltage levels (e.g., full-scale voltage level V_{OUT} and fractional-scale voltage level V_{OUT}/3), a transmitter uses only one regulated voltage (e.g., full-scale voltage level V_{OUT}) to generate a full-scale signal and selectively drives multiple distinct bottom plates of a capacitor having a single, shared top plate to transmit a fractionally-scaled signal.

Referring to FIG. 10, capacitor 1013 includes bottom plate 1004, bottom plate 1006, and top plate 1002. In at least one embodiment, top plate 1002 is a continuous conductive plate that overlaps both bottom plates. A first driver in the transmitter drives bottom plate 1004 with signal TX1 and a second driver in the transmitter drives bottom plate 1006 with signal TX2. When active, signal TX1 and signal TX2 are each full-scale signals (e.g., each have an amplitude of regulated voltage V_{OUT}). The number of bottom plates being actively driven and a ratio of the corresponding capacitance to a total capacitance when all of the bottom plates are actively driven determines the amplitude of the signal on bondwire 114. Physical design of bottom plates that are partitioned laterally or vertically (e.g., into a left half and a right half, or a top half and a bottom half, respectively) have sharp points that have very small radii of curvature, which causes the electric field near the sharp points to be very large. In addition, such partitioning results in asymmetric configurations that can increase those electric fields near edges. A very large electric field can cause high voltages at the sharp points of the capacitor, and can breakdown the dielectric material between the plates, or other reliability issues in a product including the capacitor. Accordingly, a capacitor structure that reduces or eliminates sharp points of the plate of the capacitor and improves reliability of a product including the capacitor is described below.

In at least one embodiment of an isolation communication channel, a capacitor includes multiple concentric bottom plates formed in a first conductive semiconductor layer (e.g., metal-1), a top plate formed in a second conductive semiconductor layer (e.g., metal-7) above the first conductive semiconductor layer, and a dielectric material (e.g., silicon dioxide) formed between the top plate and the bottom plates. In at least one embodiment, the bottom plates are radially symmetrical to improve high voltage reliability of the capacitor. That is, the bottom plates have similar parts regularly arranged about a central axis. In at least one embodiment, the bottom plates are rounded and have no edge discontinuities. Referring to FIGS. 11A, 11B, and 11C, bottom plate 1104 and bottom plate 1106 are oval-shaped and are concentric about center 1102. Bottom plate 1104 and bottom plate 1106 are separated by gap 1108 that is filled with a non-conducting material (e.g., a thin-film dielectric material or air). In at least one embodiment, top plate 1110 and the bottom plates are coaxial and top plate 1110 has a shape similar to the shape of the bottom plates and overlaps the bottom plates (FIG. 11B). In other embodiments, top plate 1110 has a different shape than the bottom plates, e.g., top plate 1110 has a rounded, rectangular shape, that overlaps the oval-shaped bottom plates (FIG. 11C).

Other radially symmetrical shapes may be used for the bottom plates (e.g., circular, stadium, or octagonal). FIGS. 12A and 12B illustrate bottom plate 1202, which has a stadium-shape and is surrounded by bottom plate 1204, which has an annular stadium shape. Bottom plate 1204 and bottom plate 1206 are concentric about center 1202. Bottom plate 1204 and bottom plate 1206 are separated by gap 1208 that has an annular stadium shape and is filled with a non-conducting material (e.g., a thin-film dielectric material or air). In at least one embodiment, top plate 1210 and the bottom plates are coaxial and top plate 1210 has a shape similar to the shape of the bottom plates and is coaxial with the bottom plates (FIG. 12B).

In other embodiments, other shapes are used for the bottom plate. For example, in manufacturing technologies that do not allow for completely rounded conductive plates, an octagonal shape is used to approximate a rounded shape and increases the radii of curvature of sharp points from that of rectangular-shaped plates. FIG. 13 illustrates bottom plate 1304 and bottom plate 1306 separated by gap 1308. Bottom plate 1304 and bottom plate 1306 are concentric about center 1302 and are radially symmetrical. Other embodiments of a capacitor include more than two bottom plates, thereby providing finer resolution of signal amplitudes used by the isolation communication channel (e.g., modified OOK modulation including more than two non-zero signal amplitudes). For example, FIG. 14 illustrates bottom plate 1412, bottom plate 1404, and bottom plate 1406 that are concentric about center 1402. Bottom plate 1412 and bottom plate 1404 are separated by gap 1410. Bottom plate 1404 and bottom plate 1406 are separated by gap 1408. Gaps 1408 and gap 1410 are filled with a non-conducting material (e.g., a thin-film dielectric material or air). Each bottom plate is coupled to a separate driver in the transmitter and is selectively driven with a full-scale signal.

In at least one embodiment of a capacitor having multiple bottom plates, the gap between adjacent bottom plates is only wide enough to electrically isolate the adjacent bottom plates from each other. Since the adjacent bottom plates will not experience a substantial voltage difference (e.g., at most by V_{DD}) the gap between adjacent bottom plates is much smaller than the distance between the top plate and the bottom plates, which can experience substantial voltage differences. In at least one embodiment, the gap has a width that is at least the minimum width specified by a design rule check (DRC) of a target manufacturing technology, although it may be wider than that minimum width. Thus, the area of a capacitor including multiple, concentric bottom plates and a shared top plate is not substantially larger than the area of a conventional capacitor including only one bottom plate and has a negligible increase in overall integrated circuit area.

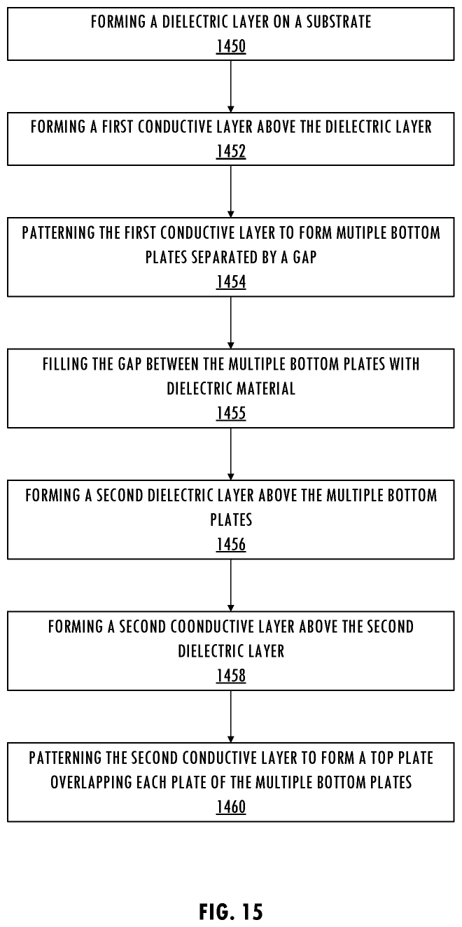

Referring to FIG. 15, a method for manufacturing an isolation communication channel having a capacitor including multiple concentric bottom plates consistent with various embodiments described herein includes forming a dielectric layer on a semiconductor substrate (1450). The method includes forming a first conductive semiconductor layer (e.g., metal-1 having a thickness of approximately 0.5 microns) above the dielectric layer (1452). The method includes patterning the first conductive layer to form multiple bottom plates using conventional photolithography techniques (1454). Each plate of the multiple bottom plates is separated from a next adjacent bottom plate by a gap. The bottom plates are radially symmetrical to improve high voltage reliability of the capacitor. In at least one embodiment, the gap between the bottom plates is filled with dielectric material (e.g., by forming a thin layer of silicon dioxide and may include additional photolithography steps or planarization steps) (1455). The method includes forming a second dielectric layer (e.g., silicon dioxide having a thickness of approximately ten microns) above the multiple bottom plates (1456). In at least one embodiment, formation of the second dielectric layer fills the gaps between the bottom plates and step 1455 is excluded. The second dielectric layer fills each gap between adjacent bottom plates of the multiple bottom plates. The method includes forming a second conductive semiconductor layer (e.g., metal-7 having a thickness of approximately 3 microns) above the second dielectric layer (1458). The method includes patterning the second conductive layer to form a top plate overlapping each plate of the multiple bottom plates using conventional photolithography techniques (1460). In an embodiment, the capacitor can withstand high voltages, e.g., voltages in the range of kilovolts (e.g., at least 5 kilovolts), across the top plate and the bottom plates. In at least one embodiment of the method, driver circuits coupled to the bottom plates and other transmitter circuits are formed using steps including 1452, 1454, 1458, and 1460 and other integrated circuit manufacturing techniques. In at least one embodiment of the method, a bondwire is attached to the top plate after integrated circuit manufacture.

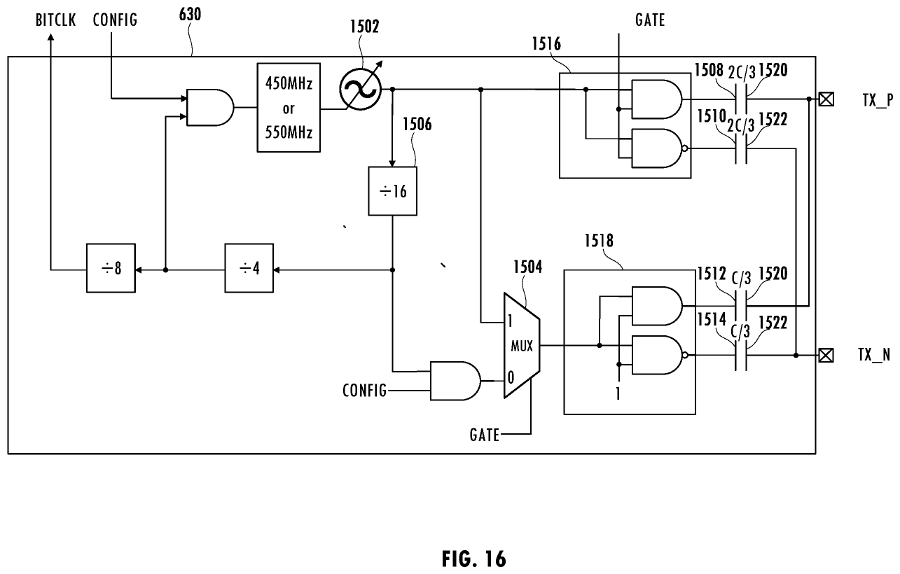

Referring to FIG. 16, an exemplary transmitter includes a differential pair of nodes TX_P and TX_N. Each of those nodes is coupled to a corresponding capacitor having multiple bottom plates and a top plate that is shared by the multiple bottom plates. For ease of illustration, the capacitor coupled to TX_P and having multiple bottom plates and a shared top plate, is illustrated using two separate capacitor symbols (e.g., capacitors having ⅔ C and ⅓ C and having top plates 1520 and bottom plates 1508 and 1512, respectively) and the capacitor coupled to TX_N and having multiple bottom plates and a shared top plate, is illustrated using two separate capacitor symbols (e.g., capacitors having ⅔ C and ⅓ C and having top plates 1522 and bottom plates 1510 and 1514, respectively) and may be implemented using physical designs described above. The capacitor coupled to TX_P and the capacitor coupled to TX_N each provides a maximum capacitance of C (e.g., ⅓ C+⅔ C). The capacitor coupled to TX_P has two bottom plates, bottom plate 1508 providing a transmit signal using ⅔ C when active and bottom plate 1512 providing an additional transmit signal using ⅓ C when active. When any capacitor bottom plate is not active, the bottom plate will be driven with ‘0.’ Similarly, the capacitor coupled to terminal TX_N has two bottom plates, bottom plate 1510 providing a transmit signal using ⅔ C when active and bottom plate 1514 providing an additional transmit signal using ⅓ C when active. When any capacitor bottom plate is not active, the bottom plate will be driven with ‘0.’

In at least one embodiment, select circuit 1516 is configured to selectively drive an OOK signal on bottom plate 1508 and bottom plate 1510, which combine with signals driven on bottom plate 1512 and bottom plate 1514, respectively. That is, signals selectively driven will result in a differential amplitude of ⅓ V_{DD} or ⅔ V_{DD}, depending on whether the signal is driven from select circuit 1516 or select circuit 1518. Accordingly, when GATE=1, the signal driven on TX_P and TX_N has a frequency of 450 MHz or 550 MHz, as provided by oscillator 1502, and a differential amplitude of V_{DD}.

When GATE=0, select circuit 1516 drives bottom plate 1508 and bottom plate 1510 to ground (i.e., logic ‘0’). Select circuit 1504 provides a signal having a frequency of clock 1502 and frequency divided by divider 1506 (e.g., approximately divide-by-16). When GATE=0 and CONFIG=0, the signal driven on TX_P and TX_N has a differential amplitude of ground and when GATE=0 and CONFIG=1, the signal driven on TX_P and TX_N has a frequency of approximately 32 kHz and a differential amplitude of V_{DD}/3. Note that the control logic and signal levels are exemplary only and finer granularity in amplitude may be generated to communicate additional information. For example, in other embodiments, select circuit 1518 is controlled by an additional control signal to selectively enable bottom plate 1512 and bottom plate 1514, thereby facilitating another signal level (e.g., amplitudes of ⅔ V_{DD}) for transmitting additional information.

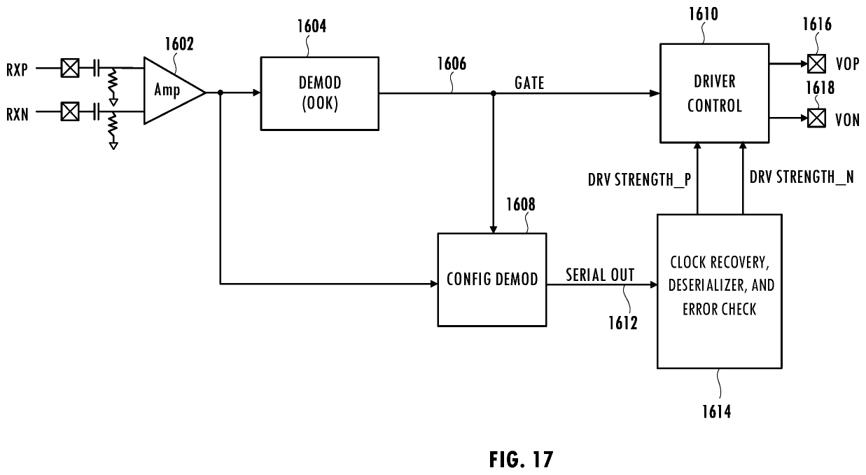

The isolation communication channel described herein may be included in any isolation application (e.g., industrial, automotive, solar inverters, power supplies, consumer, or telecom) or isolation product (e.g., digital isolators, isolated gate drivers, isolated FET drivers, isolated analog and ADCs, industrial I/O applications, isolated DC/DC converters, isolated ADC, isolated controller area network (CAN) transceivers, etc.). Referring to FIG. 17, in at least one embodiment, a receiver uses the isolation communication channel to receive a digital signal, e.g., asynchronously to an internal clock, and generates a modulated representation of the digital signal. Transmitter circuit 526 generates a carrier clock signal having carrier frequency I′, that is much greater than a frequency associated with data of the digital signal. By driving a differential pair of signals representing the data on a capacitively coupled conductor of the isolation communication channel, a transmitter circuit provides the receiver circuit of FIG. 17 with a representation of the data. The receiver senses a differential signal that was transmitted over the isolation communication channel and is received as the differential signals RXP and RXN. Those signals are amplified in one or more amplifiers 1602 and supplied to a modified OOK demodulator 1604 to recover gate information from the received differential signal and supply gate signal 1606. Gate signal 1606 and the received signal, after amplification, are supplied to configuration demodulation path 1608, which extracts configuration information from the received differential signal and supplies the configuration information to clock recovery, deserializer, and error check circuit 1614.

Clock recovery, deserializer, and error check circuit 1614 converts the serial data stream received over the isolation communication channel to a parallel word of configuration information, e.g., 3 bits, to apply as drive strength signals to driver control logic 1610. Thus, the clock recovery, deserializer, and error check circuit 1614 recovers a clock signal to sample serial out data 1612 from configuration demodulation path 1608, checks the parity bits, redundancy bits, or otherwise performs error checking to ensure the data is correct before updating the control setting of driver control circuit 1610. If errors are found, the control values are not updated. Other configuration settings may also be adjusted by the configuration information transmitted. In an embodiment of FIG. 17 two output terminals 1616 and 1618 are used to supply the turn on and turn off signals for the gate signal, which are combined externally to drive a power transistor. VOP pin 1616 provides the positive drive current to turn on the power transistor and VON pin 1618 provides the sinking current to turn off the power transistor. Other embodiments utilize a single output terminal for the gate signal. The strengths of drive currents provided by driver control logic 1610 are adjusted using the configuration information.

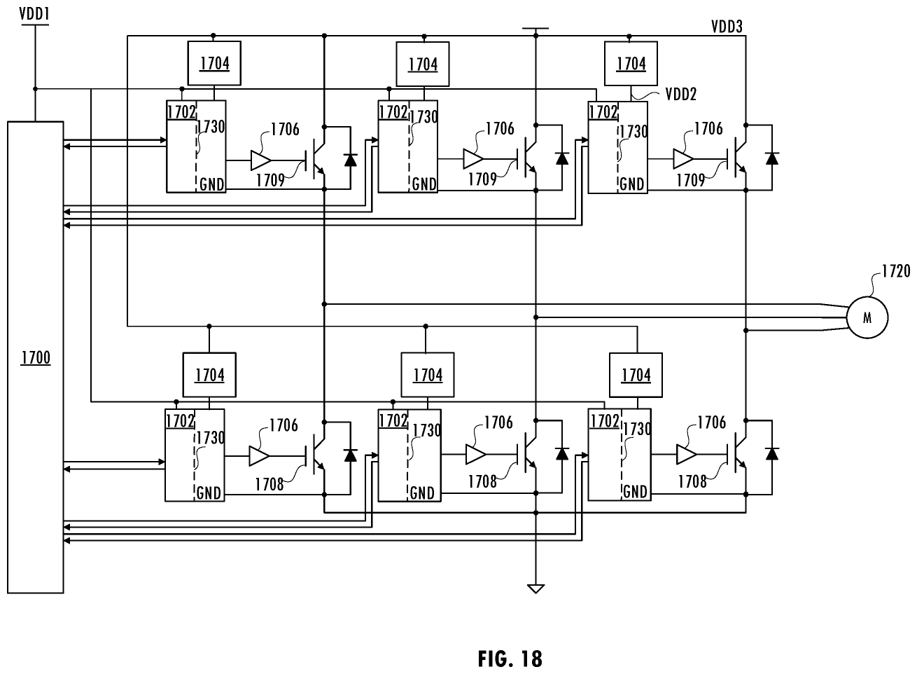

Referring to FIG. 18 in an exemplary motor control application, processor 1700, which may be a microprocessor, microcontroller, or other suitable processing device, operates in a first domain (i.e., V_{DD1}, e.g., 5 Volts (V)) and provides one or more signals for a high-power load system operating in a second domain (i.e., V_{DD3}, e.g., 800 V). Systems 1702 each include an isolation barrier 1730 and an isolation communications channel that includes the capacitor structure to support variable signal amplitudes, as described above, for safely communicating information and control signals from processor 1700 to drivers 1706, which drive high-power drive devices 1708 and 1709 of a three-phase inverter used to deliver three-phase power to motor 1720. Exemplary high-power drive devices include power metal-oxide-semiconductor field-effect transistors (MOSFETs), insulated-gate bipolar transistors (IGBTs), Gallium-Nitride (GaN) MOSFETs, Silicon-Carbide power MOSFETs, or other suitable devices able to deliver high currents over short periods of time.

Voltage converters 1704 convert an available power supply voltage from V_{DD1} or V_{DD3} to a voltage level (i.e., V_{DD2}, e.g., approximately 15 V) usable by the high-voltage side of systems 1702 and drivers 1706. Note that in other embodiments, a single voltage converter 1704 converts one power supply voltage from a first voltage level (e.g., V_{DD3}) to multiple other voltage levels (e.g., V_{DD1} and V_{DD2}) and/or provides multiple outputs of a particular voltage (e.g., multiple V_{DD2} outputs corresponding to multiple systems 1702). Drivers 1706 provide switch control signals at levels required by corresponding high-power drive devices 1708 or 1709 of the three-phase inverter. The load motor requires three-phase power at high power levels. Systems 1702 that correspond to high-power devices coupled to V_{DD3} (high-side inverter devices), are grounded at a voltage that is switching with respect to earth ground by the high voltage levels of V_{DD3}. Typical high-power drive devices 1708 and 1709 of the three-phase inverter that are used to drive motor 1720 require substantial turn-on voltages (e.g., voltages in the range of tens of Volts).

The description of the invention set forth herein is illustrative and is not intended to limit the scope of the invention as set forth in the following claims. The terms “first,” “second,” “third,” and so forth, as used in the claims, unless otherwise clear by context, is to distinguish between different items in the claims and does not otherwise indicate or imply any order in time, location or quality. For example, “a first received network signal,” “a second received network signal,” does not indicate or imply that the first received network signal occurs in time before the second received network signal. Variations and modifications of the embodiments disclosed herein may be made based on the description set forth herein, without departing from the scope of the invention as set forth in the following claims.

What is claimed is:

1. A capacitor comprising:
a first plate formed in a first conductive integrated circuit layer; and
multiple second plates formed in a second conductive integrated circuit layer, each second plate of the multiple second plates being separated from a next adjacent second plate by a gap in the second conductive integrated circuit layer, the multiple second plates being concentric.

2. The capacitor as recited in claim 1 wherein the multiple second plates are radially symmetrical.

3. The capacitor as recited in claim 1 wherein each second plate of the multiple second plates is responsive to a corresponding signal of a plurality of signals generated by a transmitter circuit.

4. The capacitor as recited in claim 3 wherein the plurality of signals are identical, full-scale periodic signals in a first configuration of the capacitor.

5. The capacitor as recited in claim 4 wherein a first signal of the plurality of signals is a full-scale periodic signal of the full-scale periodic signals and a second signal of the plurality of signals is inactive in a second configuration of the capacitor.

6. The capacitor as recited in claim 1 wherein a centermost second plate of the multiple second plates is stadium-shaped and each other of the multiple second plates has an annular stadium shape and surrounds the centermost second plate.

7. The capacitor as recited in claim 1 wherein the gap has a maximum width of a few times a minimum space width.

8. The capacitor as recited in claim 1 wherein a ratio of a first area of a second plate of the multiple second plates to a total area of the multiple second plates determines a voltage level of a signal transmitted using the capacitor.

9. The capacitor as recited in claim 1 wherein the first plate overlaps each conductive plate of the multiple second plates.

10. The capacitor as recited in claim 1 wherein the first plate is a continuous conductive structure.

11. The capacitor as recited in claim 1 further comprising a dielectric integrated circuit layer separating the first conductive integrated circuit layer and the second conductive integrated circuit layer by a first width much greater than a second width of the gap.

12. A method for communicating information across an isolation barrier, the method comprising:
selectively driving each plate of multiple first plates of a capacitor using a full-scale signal according to a first control signal, the capacitor having the multiple first plates and a second plate.

13. The method as recited in claim 12 further comprising adjusting a frequency of the full-scale signal using the first control signal.

14. The method as recited in claim 12 further comprising selecting a frequency of the full-scale signal using the first control signal and a second control signal.

15. The method as recited in claim 12 wherein the selectively driving adjusts an amplitude of a signal communicated across the isolation barrier using the capacitor.

16. The method as recited in claim 15 wherein the amplitude is based on a first area of the second plate overlapping each of the multiple first plates.

17. A method for manufacturing an isolation communication channel, the method comprising:
forming a conductive integrated circuit layer using a substrate; and
patterning the conductive integrated circuit layer to form multiple plates of a capacitor, each plate of the multiple plates being separated from a next adjacent plate by a gap in the conductive integrated circuit layer, the multiple plates being concentric.

18. The method as recited in claim 17 wherein the multiple plates are radially symmetrical.

19. The method as recited in claim 17 further comprising:
forming an insulating layer using the substrate;
forming a second conductive integrated circuit layer using the substrate, the insulating layer being formed between the conductive integrated circuit layer and the second conductive integrated circuit layer; and
patterning the second conductive integrated circuit layer to form a second plate of the capacitor at least partially overlapping each of the multiple plates.

20. An isolator product manufactured by the method as recited in claim 17.
